(19) United States
(12) Patent Application Publication
(10) Pub. No.: US 2026/0187298 A1
(43) Pub. Date: Jul. 2, 2026

(54) Interior Layout Design based on Multilayer Graphs

(71) Applicant: International Business Machines Corporation, Armonk, NY (US)

(72) Inventors: Han Wang, Shanghai (CN); Da Peng Yin, Dalian (CN); Xiao Fei Wang, ShenYang (CN)

(21) Appl. No.: 19/007,646

(22) Filed: Jan. 2, 2025

(51) Int. Cl. G06F 30/13

(52) U.S. Cl. CPC G06F 30/13

(57) ABSTRACT

A method creates a floor plan. A floor plan input comprising an input boundary and a number of room types and room quantities is received. A furniture input comprising a number of furniture types and furniture quantities is received. A room layer graph is generated using the floor plan input. A furniture layer graph for rooms in the room layer graph is generated using the furniture input. A multilayer graph for the floor plan is created using the room layer graph and the furniture layer graph.

### BACKGROUND

The disclosure relates generally to a computer system and more specifically to generating interior layouts using multilayer graphs.

In designing interior layouts, designers can refer to historical data from prior interior layouts. Often times in selecting or planning new interior layouts, customers look to existing layouts from other houses or buildings that they find appealing or meeting the desired functionality.

These prior interior layouts can be used to guide the design process, providing ideas on effective room arrangements, aesthetic styles, and space optimization techniques. These layouts are also referred to as floor plans and can be adapted to fit the specific dimensions, requirements, and purposes of the design being generated.

Various software packages can be used to import, modify, and provide visualization of these prior floor plans. Further, the software packages can also be used to make modifications to the prior floor plans to meet the requirements of the current project.

### SUMMARY

According to one illustrative embodiment, a method creates a floor plan. A floor plan input comprising an input boundary and a number of room types and room quantities is received. A furniture input comprising a number of furniture types and furniture quantities is received. A room layer graph is generated using the floor plan input. A furniture layer graph for rooms in the room layer graph is generated using the furniture input. A multilayer graph for the floor plan is created using the room layer graph and the furniture layer graph. According to other illustrative embodiments, a computer system and a computer program product for creating a floor plan are provided.

### BRIEF DESCRIPTION OF THE DRAWINGS

FIG. 1 is a block diagram of a computing environment in accordance with an illustrative embodiment;

FIG. 2 is a block diagram of a layout environment in accordance with an illustrative embodiment;

FIG. 3 is an illustration of generating pixel functions using column projection in accordance with an illustrative embodiment;

FIG. 4 is an illustration of creating a room layer graph in accordance with an illustrative embodiment;

FIG. 5 is an illustration of furniture assignment using a Markov graph process in accordance with an illustrative embodiment;

FIG. 6 is an illustration of a multilayer graph in accordance with an illustrative embodiment;

FIG. 7 is a flow diagram of a process for generating a multilayer graph for a floor plan in accordance with an illustrative embodiment;

FIG. 8 is a flow diagram of a process for generating a room layer graph in accordance with an illustrative embodiment;

FIG. 9 is a flow diagram of a process for generating a furniture layer graph in accordance with an illustrative embodiment;

FIG. 10 is a flow diagram for determining the furniture potential value from a furniture potential function in accordance with an illustrative embodiment;

FIG. 11 is a flowchart of a process for creating a floor plan in accordance with an illustrative embodiment;

FIG. 12 is a flowchart of a process for generating a room layer graph in accordance with an illustrative embodiment;

FIG. 13 is a flowchart of a process for identifying a room graph in accordance with an illustrative embodiment;

FIG. 14 is a flowchart of a process for determining the room layout design in accordance with an illustrative embodiment;

FIG. 15 is a flowchart of a process for generating room layout images in accordance with an illustrative embodiment;

FIG. 16 is a flowchart of a process for generating a furniture layer graph in accordance with an illustrative embodiment; and

FIG. 17 is a block diagram of a data processing system in accordance with an illustrative embodiment.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

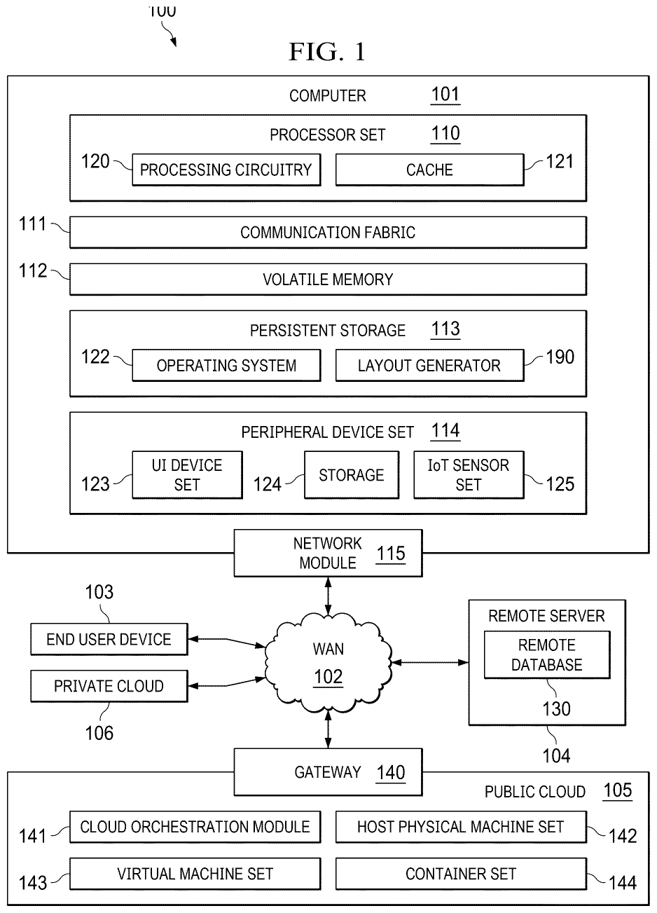

With reference now to the figures in particular with reference to FIG. 1, a block diagram of a computing environment is depicted in accordance with an illustrative embodiment. Computing environment 100 contains an example of an environment for the execution of at least some of the computer code involved in performing the inventive methods, such as layout generator 190. In addition to layout generator 190, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and layout generator 190, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in layout generator 190 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in layout generator 190 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES: Public cloud 105 and private cloud 106 are programmed and configured to deliver cloud computing services and/or microservices (not separately shown in FIG. 1). Unless otherwise indicated, the word “microservices” shall be interpreted as inclusive of larger “services” regardless of size. Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The illustrative embodiments recognize and take into account one or more different considerations as described herein. Previously generated floor plans can be stored in databases as graphs. For example, a floor plan can be described using graphs comprising graph nodes and edges. The graph nodes represent rooms within this floor plan. Each graph node can include the room type, the area of the room and room position. The edges show the connections between rooms in the floor plan.

However, these graph nodes lack details for the rooms. For example, the details such as furniture that may be located in these rooms are not present in a graph node.

Thus, illustrative examples provide a method, apparatus, computer system, and computer program product for creating a floor plan. In one illustrative example, a floor plan input is received in which this input comprises an input boundary and a number of room types and room quantities. A furniture input is received in which the furniture input comprises a number of furniture types and furniture quantities. A room layer graph is generated using the floor plan input. A furniture layer graph is generated for rooms in the room layer graph using the furniture input. A multilayer graph for the floor plan is created using the room layer graph and the furniture layer graph.

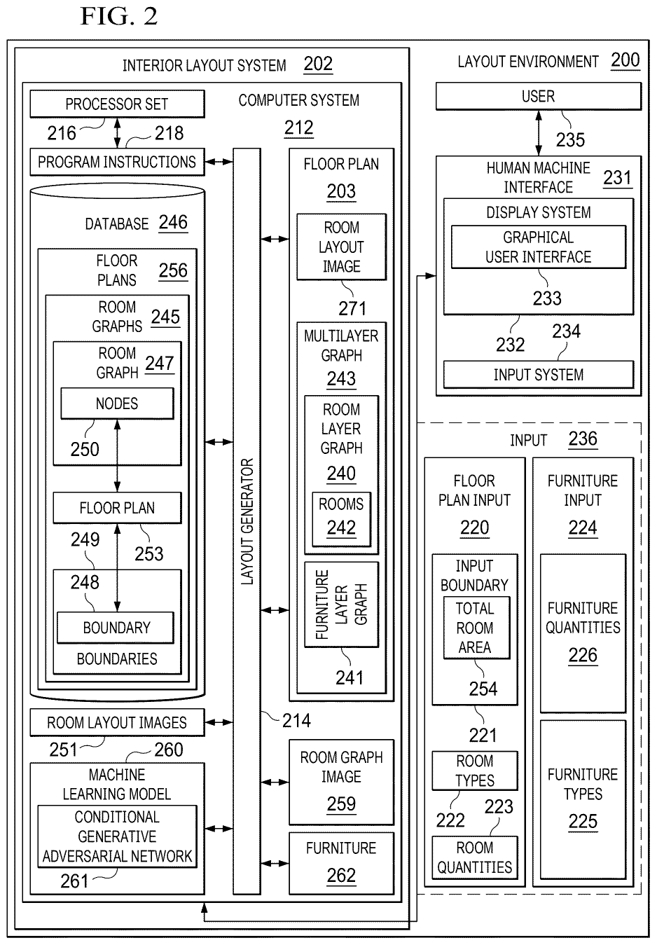

With reference now to FIG. 2, a block diagram of a layout environment is depicted in accordance with an illustrative embodiment. In this illustrative example, layout environment 200 includes components that can be implemented in hardware such as the hardware shown in computing environment 100 in FIG. 1. In this example, interior layout system 202 can operate to generate floor plan 203. This floor plan includes room layer graph 240, furniture layer graph 241, and room layout image 271. Layout generator 214 may be implemented using layout generator 190 in FIG. 1.

In this illustrative example, interior layout system 202 comprises computer system 212 and layout generator 214. Layout generator 214 is located in computer system 212.

Layout generator 214 can be implemented in software, hardware, firmware or a combination thereof. When software is used, the operations performed by layout generator 214 can be implemented in program instructions configured to run on hardware, such as a processor unit. When firmware is used, the operations performed by layout generator 214 can be implemented in program instructions and data and stored in persistent memory to run on a processor unit. When hardware is employed, the hardware can include circuits that operate to perform the operations in layout generator 214.

In the illustrative examples, the hardware can take a form selected from at least one of a circuit system, an integrated circuit, an application-specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field-programmable logic array, a field-programmable gate array, and other suitable hardware devices. Additionally, the processes can be implemented in organic components integrated with inorganic components and can be comprised entirely of organic components excluding a human being. For example, the processes can be implemented as circuits in organic semiconductors.

As used herein, “a number of” when used with reference to items, means one or more items. For example, “a number of operations” is one or more operations.

Further, the phrase “at least one of,” when used with a list of items, means different combinations of one or more of the listed items can be used, and only one of each item in the list may be needed. In other words, “at least one of” means any combination of items and a number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combination of these items can be present. In some illustrative examples, “at least one of” can be, for example, without limitation, two of item A; one of item B; and ten of item C; four of item B and seven of item C; or other suitable combinations.

Computer system 212 is a physical hardware system and includes one or more data processing systems. When more than one data processing system is present in computer system 212, those data processing systems are in communication with each other using a communications medium. The communications medium can be a network. The data processing systems can be selected from at least one of a computer, a server computer, a tablet computer, or some other suitable data processing system.

As depicted, computer system 212 includes processor set 216 that is capable of executing program instructions 218 implementing processes in the illustrative examples. In other words, program instructions 218 are computer-readable program instructions. Processor set 216 is an example of processor set 110 in FIG. 1.

As used herein, a processor unit in processor set 216 is a hardware device and is comprised of hardware circuits such as those on an integrated circuit that respond to and process instructions and program code that operate a computer. Processor set 216 can be a number of processor units that can be implemented using processor set 110 in FIG. 1. The processor units can also be referred to as computer processors. When processor set 216 executes program instructions 218 for a process, processor set 216 can be one or more processor units that are in the same computer or in different computers. In other words, the process can be distributed between processor units in processor set 216 on the same or different computers in computer system 212.

Further, processor set 216 can include the same type or different types of processor units. For example, processor set 216 can be selected from at least one of a single core processor, a dual-core processor, a multi-processor core, a general-purpose central processing unit (CPU), a graphics processing unit (GPU), a digital signal processor (DSP), or some other type of processor unit.

Although not shown, processor set 216 can also include other components in addition to the processor units or processing circuitry. For example, processor set 216 can also include a cache or other components used with processor units or other processing circuitry.

In this example, layout generator 214 operates to create floor plan 203. Layout generator 214 receives floor plan input 220 comprising input boundary 221 and a number of room types 222 and room quantities 223. Further, layout generator 214 receives furniture input 224 comprising a number of furniture types 225 and furniture quantities 226.

In this illustrative example, input 236 comprises floor plan input 220 and furniture input 224 can be received by layout generator 214 from user 235 operating human machine interface (HMI) 231. As depicted, human machine interface 231 comprises display system 232 and input system 234. Display system 232 is a physical hardware system and includes one or more display devices on which graphical user interface 233 can be displayed. The display devices can include at least one of a light emitting diode (LED) display, an organic light emitting diode (OLED) display, a computer monitor, a projector, a flat panel display, a heads-up display (HUD), a head-mounted display (HMD), smart glasses, augmented reality glasses, or some other suitable device that can output information for the visual presentation of information.

Input system 234 is a physical hardware system and can be selected from at least one of a mouse, a keyboard, a touch pad, a trackball, a touchscreen, a stylus, a motion sensing input device, a gesture detection device, a data glove, a cyber glove, a haptic feedback device, or some other suitable type of input device. In this example, user 235 is a person that can interact with graphical user interface 233 through input 236 generated by input system 234. In this example, input 236 includes floor plan input 220 and furniture input 224.

Layout generator 214 generates room layer graph 240 using the floor plan input 220. In this example, room layer graph 240 defines rooms 242. Layout generator 214 also generates furniture layer graph 241 for rooms in the room layer graph using the furniture input 224. Layout generator 214 creates multilayer graph 243 for floor plan 203 using room layer graph 240 and furniture layer graph 241.

In this example, room layer graph 240 can be generated using room graphs 245 in database 246. Database 246 is a historical database containing floor plans 256 for existing floor plans. As depicted, floor plans 256 comprise boundaries 249 and room graphs 245.

Each floor plan in floor plans 256 includes a boundary and a room graph. A room graph for a floor plan comprises nodes representing rooms within the boundary of the floor plan. For example, layout generator 214 identifies room graph 247 in room graphs 245 with boundary 248 for floor plan 253 having a closest fit to input boundary 221.

The identification of room graph 247 in room graphs 245 by layout generator 214 can be made by identifying floor plans having room graphs that match the number of room types 222 and room quantities 223 in floor plan input 220. Boundaries 249 for those floor plans that have matches to the number of room types 222 and room quantities 223 can then be compared to input boundary 221 to find a closest fit.

In this example, layout generator 214 generates room graph image 259 from nodes 250 in room graph 247 in floor plan 253 and input boundary 221. Nodes 250 represent the number of room types 222 and room quantities 223. In this example, each node represents a room of a particular room type. Layout generator 214 places nodes 250 for room graph 247 into input boundary 221 to form room graph image 259.

Layout generator 214 generates room layout images 251 using room graph image 259. In this illustrative example, these layout images are permutations of the physical layout of rooms within input boundary 221 that can occur using nodes 250 from room graph 247. Each of these layout images includes external walls, doors, and the room layout inside the input boundary. The room layout can use different colors or other graphical indicators within nodes 250 for the rooms to indicate the room type.

In this illustrative example, room layout images 251 are visual representations of rooms 242 within input boundary 221. In this example, layout generator 214 can generate room layout images 251 using room graph image 259 and machine learning model 260. In this example, machine learning model 260 can be conditional generative adversarial network (cGAN) 261, which is a deep learning model that is a type of machine learning model.

Layout generator 214 creates room layer graph 240 using a selection of a room layout image in room layout images 251 as a preferred design for floor plan 203. In this example, in generating room layer graph 240, layout generator 214 can display room layout images 251 on human machine interface 231. These images provide a visualization of permutations of the physical layout of rooms within input boundary 221. Layout generator 214 can receive a user input that is a selection of the room layout image from room layout images 251 as the preferred design. Layout generator 214 uses the selected room layout image to form room layer graph 240.

In generating furniture layer graph 241, layout generator 214 assigns furniture 262 to rooms 242 in room layer graph 240 to form furniture layer graph 241 using a Markov graph process that determines furniture potentials for the furniture taking into account prior furniture placements. A furniture potential is an indication of the quality of the placement of furniture in a room. This potential can take into account prior placements of furniture for furniture already placed in a room.

In this example, the assignment of furniture is based on furniture input 224 for defining a number of furniture types 225 and furniture quantities 226. The furniture potentials take into account a suitability of the furniture based on a furniture type and a room type; a remaining available area in the rooms; and a compatibility between the furniture in a room.

The illustration of layout environment 200 in FIG. 2 is not meant to imply physical or architectural limitations to the manner in which an illustrative embodiment can be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

In other illustrative examples, the selection of the room layout image can be performed by user 235 in the form of a program or computer implemented process that can make selections based on different factors, weights, or requirements for floor plan 203. As another example, floor plan input 220 can include other inputs such as a total room area 254. An area range can be set based on specific value of the total room area according to requirements for floor plan 253. For example, if the input for the room area is 200 m², floor plans with the area range of 100 m² to 300 m² may be acceptable for total room area 254. The total room area can affect the room positions and shapes. With this input, areas of rooms in room layer graph 240 can be obtained based on the total room area, a boundary area inside the input boundary, and a room area of each room in room layout image 271 that was selected for use.

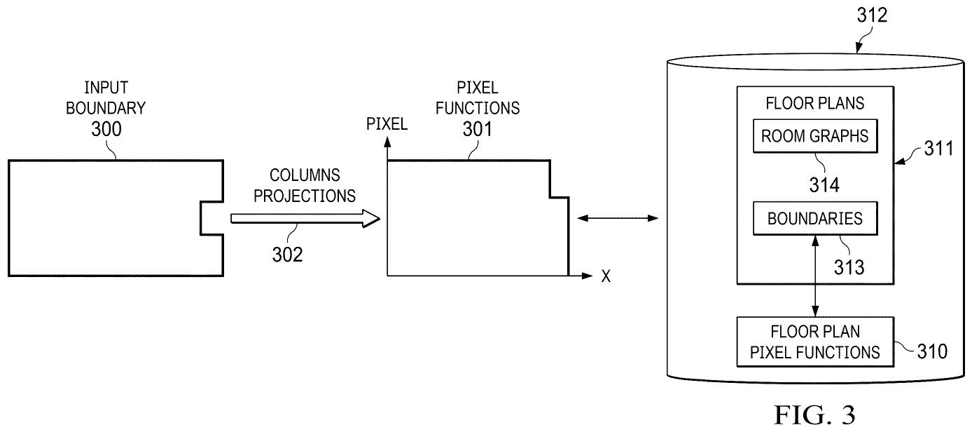

With reference to FIG. 3, an illustration of generating pixel functions using column projection is depicted with an illustrative embodiment. In this example, input boundary 300 is used to generate pixel functions 301 through column projections 302. In this example, input boundary 300 is an example of input boundary 221 in FIG. 2.

A pixel function in pixel functions 301 identifies pixels in an image input boundary 221 that are within input boundary 221 using column projections 302. Column projections 302 involve aggregating pixel data for input boundary 300 along vertical lines such as columns to form a pixel function. This type of projection compresses information into a single horizontal or x-axis. This column projection can be determined for a column by summing, averaging, or otherwise aggregating pixel intensities or features for all rows in the column.

In this example, the different pixel functions for pixel functions 301 can be determined through rotation, flipping, and other manipulations of input boundary 300. The use column projections 302 of pixel functions 301 generated from column projections 302 can enable handling irregular shapes.

Pixel functions 301 are compared to floor plan pixel functions 310 for floor plans 311 in database 312. In this example, floor plan pixel functions 310 are generated from boundaries 313 for floor plans 311. Floor plans 311 also include room graphs 314.

The comparison of pixel functions 301 to floor plan pixel functions 310 can be performed to determine a floor plan in floor plans 311 having the best fit to input boundary 300. This comparison of pixel functions 301 can be used to identify a room graph in room graphs 314. The room graph identified is the room graph in the floor plan with the boundary having the best fit to input boundary 300 as determined through the comparison of the pixel functions.

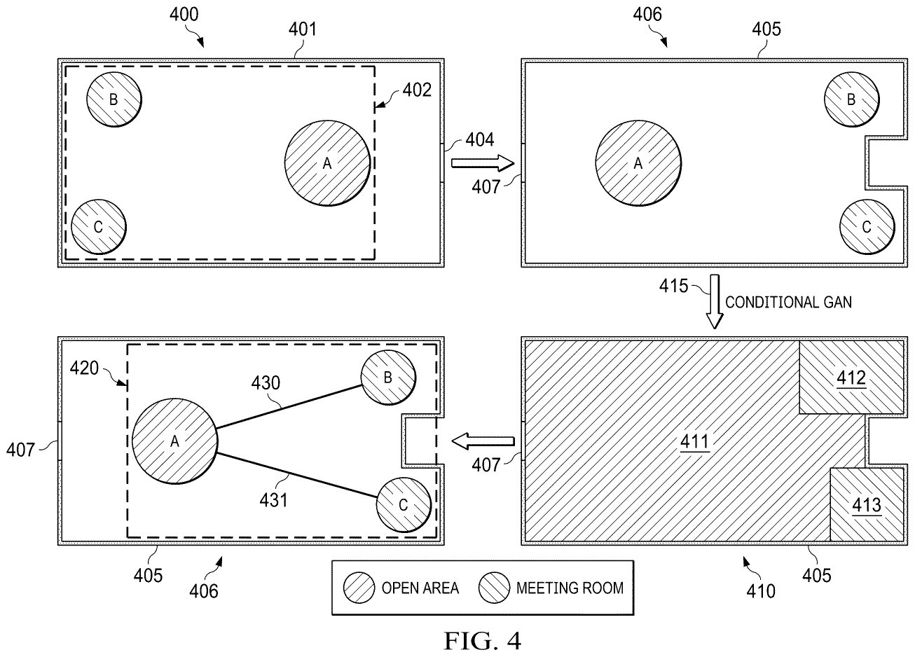

With reference next to FIG. 4, an illustration of creating a room layer graph is depicted with an illustrative embodiment. In this illustrative example, floor plan 400 comprises boundary 401 and room graph 402. Floor plan 400 is an example of a floor plan in floor plans 311 in FIG. 3. In this illustrative example, boundary 401 also includes doorway 404. Room graph 402 comprises nodes representing rooms within boundary 401. In this example, these nodes are room A, room B, and room C. Room graph 402 can also include other information such as room adjacency, room sizes, and other information. In this example, only nodes are used. The room type can be indicated for the nodes using color or other graphical indicators. As depicted in this example, room A is a room with an open area. Room B and room C are meeting rooms.

As depicted, room A, room B, and room C are placed into input boundary 405 to form room graph image 406. In this example, input boundary 405 has doorway 407. In this example, boundary 401 has the closest fit to input boundary 405 even though the doorways are in opposite locations with respect to each other. As depicted, the positioning of nodes relative to each other are flipped from locations in boundary 401 as compared to input boundary 405 based on the locations of the doorways.

Room graph image 406 is used to generate room layout image 410. In this example, room layout image 410 comprises room 411 corresponding to node A; room 412 corresponding to node B; and room 413 corresponding to node C. As depicted, the nodes from room graph 402 are used in room graph image 406 without including room sizes and adjacency of room. This usage of room graph image 406 can increase diversity in potential floor plans.

Further, pixel functions 301 in FIG. 3 can be used to determine the boundary area inside input boundary 405 and the room area of each room in the room layout image 271 that was selected. The pixels for a room, wall, door, or background can be determined using these values. As a result, the number of pixels in the input boundary and for each room can be determined for each room through image analysis.

Both the total number of pixels inside input boundary 405 and the number of pixels in each room in the selected room layout image can be obtained based on the selected room layout image through image analysis processes. These numbers of pixels are used to determine the boundary area inside input boundary 405 and the area of each room.

For example, room layout image 410 has dimensions of 293 pixels (length)*177 pixels (height). Thus, the boundary area has 293*177 pixels. In this example, each pixel has RGB values, such as R:255, G:0, B:0” for to red. In room layout image 410, every pixel represents the same area. In this example, the total pixel number inside input boundary 405 is 45,000, and each pixel is 0.01 m². With total number of pixels of 45,000 inside input boundary 405, the total room area is 450 m²in input boundary 405.

In this illustrative example, room graph image 406 is used to generate room layout image 410. In this example, a conditional generative adversarial network (cGAN) 415 can be used to generate room layout image 410 from room graph image 406. The conditional generative adversarial network can be, for example, pix2pix, pix2pixHD, or some other suitable conditional generative adversarial network. In this example, input boundary 405 and the nodes (node A, node B, and node C arguments) are the conditions used by conditional generative adversarial network (GAN) 415.

In these examples multiple room layout images are generated in which variations are present from using room graph image 406 without room sizes or adjacency conditions. These different layout images provide visualizations that can be displayed for selection by a user. The layout image, such as room layout image 410 that is selected as the preferred design is used to form room layer graph 420, which is a form of the floor plan.

In this example, edge 430 between room A and room B and edge 431 between room A and room C can be used to indicate adjacency between the rooms represented by these edges. Further, the nodes in room layer graph 420 can also include information such as room type, position, size, and other information.

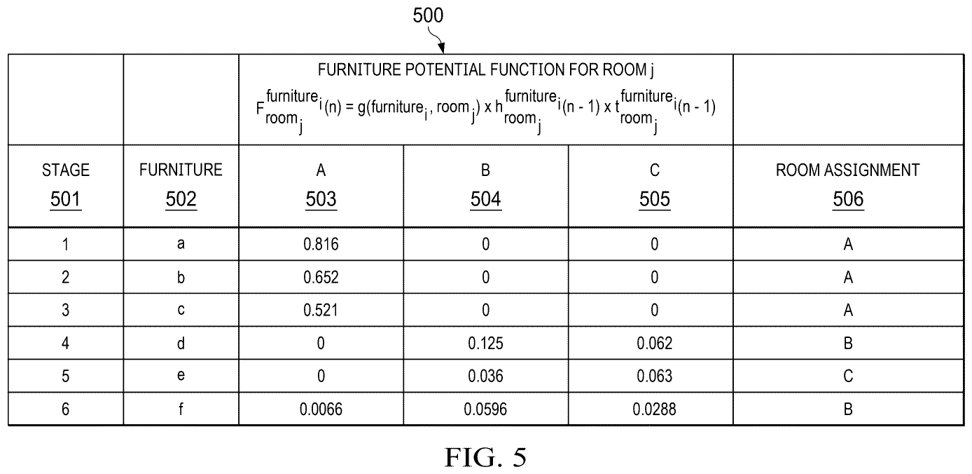

Next in FIG. 5, an illustration of furniture assignment using a Markov graph process is depicted in accordance with an illustrative embodiment. As depicted, table 500 illustrates an example of furniture assignment for creating a furniture layer graph. As depicted, table 500 has the following columns: stage 501, furniture 502, potential room A 503, potential room B 504, potential room C 505, and room assignment 506.

Stage 501 identifies a sequence of steps for placing furniture in rooms. In this illustrative example, each row corresponds to one of the stages. In this illustrative example, furniture a, furniture b, and furniture c are face-to-face desks; furniture d and furniture e are conference room tables; and furniture f is a television.

In table 500, potential room A 503 is a furniture potential for placing a piece of furniture in room A; potential room B 504 is a furniture potential for placing a piece of furniture in room B; and potential room C 505 is a furniture potential for placing a piece of furniture in room C. This furniture potential is used in a Markov graph process to assign furniture to the different rooms in a manner that takes into account the status of furniture placement from a previous stage.

In these examples, the process of making furniture assignments to create a furniture layer graph takes into account a number of furniture types and quantities received in furniture input. These quantities act as constraints in the Markov graph process to assign furniture to different rooms.

In the illustrative example, a Markov graph process is used to assign each piece of furniture to a suitable room involved in room layer graph one after another. The assignment uses a furniture potential function

$${F}_{{room}_{j}}^{furnitur {e}_{i}} ( n )$$

in which furniture is a piece of furniture, i is a furniture index, room is a room, j is a room index, and n is a stage identifier. When assigning furniture i at stage n, the process calculates potential function

$${F}_{{room}_{j}}^{furnitur {e}_{i}} ( n )$$

for all j and maps these function values except for 0 to probabilities using softmax function. The furniture potential function indicates the quality of the placement of furniture based on factors. In this example, the factors include furniture type versus room type; remaining room area after placement of a piece of furniture; and compatibility between a potential placement of a piece of furniture and furniture already placed.

In this example furniture i is assigned randomly based on probabilities. In the Markov graph, the furniture potential function is as follows

$${F}_{{room}_{j}}^{furnitur {e}_{i}} ( n ) = g ( {furniture}_{i} , {room}_{j} ) \times {h}_{{r}_{oomj}}^{furnitur {e}_{i}} ( n - 1 ) \times {t}_{{r}_{oomj}}^{{furniture}_{i}} ( n - 1 )$$

where

$${F}_{{room}_{j}}^{furnitur {e}_{i}} ( n )$$

refers to the potential function to put furniture i in room j at stage n.
g(furnitureᵢ, roomⱼ) is a furniture-room function to put furniture i in room j;

$${h}_{{room}_{j}}^{furnitur {e}_{i}} ( n - 1 )$$

is a furniture-area function to put furniture i in room j at the end of stage n−1;

$${t}_{{room}_{j}}^{furnitur {e}_{i}} ( n - 1 )$$

is a furniture control function to put furniture i in room j at the end of stage n−1.

In this example,

$$g ( {furniture}_{i} , {room}_{j} ) = \{ \begin{matrix}1 , if furniture i is a face - to - face desk while {room}_{j} \\ is an open area , or furniture i is a conference \\ room table while room j is a meeting room \\ 0 , if furniture i is a face - to - face desk while {room}_{j} \\ is a meeting room , or furniture i is a conference room \\ table while room j is an open area \\ 0.3 , if furniture i is a television while room j is an open area \\ 0.7 , if furniture i is a television while room j is a meeting room\end{matrix}$$

$${h}_{{room}_{j}}^{{furniture}_{i}} ( n ) = \{ \begin{matrix}0 , if {remainarea}_{n} ( {room}_{j} ) \leq size ( {furniture}_{i} ) \\ \frac{{remainarea}_{n} ( {room}_{j} )}{{\sum }_{k} {remainarea}_{n} ( {room}_{k} )} , else\end{matrix}$$

where remainareaₙ(roomⱼ) refers to the remaining available area in room j at the end of stage n; k refers to all possible rooms.

$${f}_{{room}_{j}}^{{f}_{urniture i}} ( n - 1 ) = \{ \begin{matrix}1 , if there no furniture in room j at the end of stage n - 1 \\ {0.8}^{x} , if furniture i is a face - to - face desk while there are x \\ face - to - face desks in room j at the and of stage n - 1 \\ {0.7}^{x} , condition 1 \\ {0.3}^{x} , condition 2 \\ {0.1}^{x} , condition 3\end{matrix}$$

where condition 1 is that if furniture i is a conference room table while there are x televisions in room j at the end of stage n−1, or furniture i is a television while there are x conference room tables in room j at the end of stage n−1; condition 2 is that if furniture i is a face-to-face desk while there are x televisions in room j at the end of stage n−1, or furniture i is a conference room table while there are x conference room tables in room j at the end of stage n−1, or furniture i is a television while there are x face-to-face desks in room j at the end of stage n−1; condition 3 is that if furniture i is a face-to-face desk while there are x conference room tables in room j at the end of stage n−1, or furniture i is a conference room table while there are x face-to-face desks in room j at the end of stage n−1, or furniture i is a television while there are x televisions in room j at the end of stage n−1.

Room assignment 506 identifies the room where a piece of furniture identified in furniture 502 is assigned. The assignment is based on selecting the room with the probabilities calculated by the furniture potential function in potential room A 503; potential room B 504 and potential room C 505.

For example, in stage 1, furniture a has a furniture potential of 0.816 for room A and zero for room B and room C. The probability is then 1 for room A and zero for room B and room C. Thus, furniture a is placed in room A. As another example, in stage 4, furniture d has a potential of zero for room A′ a potential of 0.125 for room B, and 0.062 for room C. These values take into account the placement of furniture in prior stages. In this case, furniture d is more likely to be placed in room B.

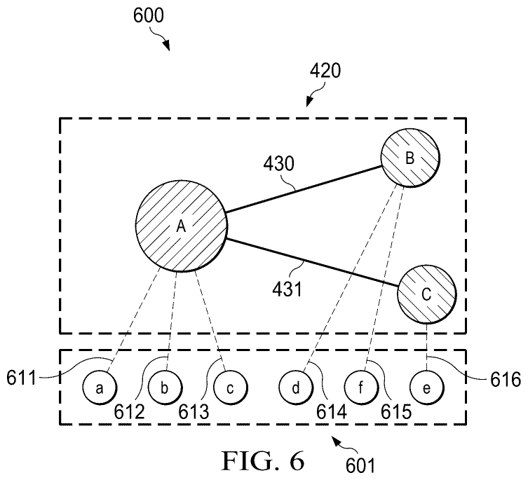

With reference now to FIG. 6, an illustration of a multilayer graph is depicted in accordance with an illustrative embodiment. Multilayer graph 600 is an example of multilayer graph 243 in FIG. 2. In the illustrative examples, the same reference numeral may be used in more than one figure. This reuse of a reference numeral in different figures represents the same element in the different figures.

As depicted, multilayer graph 600 includes room layer graph 420 from FIG. 4 and furniture layer graph 601. Room layer graph 420 is an example of room layer graph 240 in FIG. 2 and furniture layer graph 601 is an example of furniture layer graph 241 in FIG. 2. In this example, in addition to edge 430 connects room A and room B and edge 431 connects room A and room C room, layer graph 420 also includes other information such as room type, room size, and room locations. In one example, room type can be indicated by colors used for the nodes. Other information may not be visually depicted,

Furniture layer graph 601 comprises furniture node a, furniture node b, furniture node c, furniture node d, furniture node e, and furniture node f. The edges these furniture nodes to room nodes show the rooms within room layer graph 420 in which the furniture is located. As depicted, edge 611 connects furniture node a to room A, edge 612 connects furniture b to room A, edge 613 connects furniture c to room A, edge 614 connects furniture d to room B, edge 615 connects furniture f to room B, and edge 616 furniture e to room C. In this example, this placement of furniture is based on potential values generated as described using a Markov graph process involving a furniture potential function in FIG. 5.

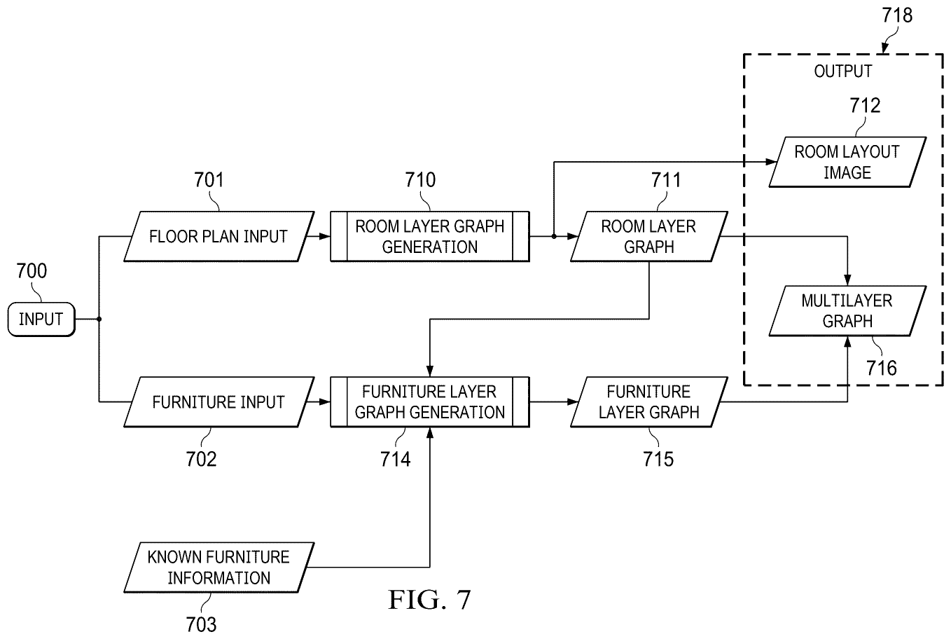

With reference now to FIG. 7, a flow diagram of a process for generating a multilayer graph for a floor plan is depicted in accordance with an illustrative embodiment. The process in FIG. 7 can be implemented in hardware, software, or both. When implemented in software, the process can take the form of program instructions that are run by a processor set located in one or more hardware devices in one or more computer systems. For example, the process can be implemented in layout generator 214 in computer system 212 in FIG. 2. This flow diagram is an example of the flow used to generate multilayer graph 243 in FIG. 2.

In this example, input 700 comprises floor plan input 701 and furniture input 702. Floor plan input 701 includes information such as an input boundary that identifies external walls and doors. This input also includes a number of room types and quantities for the floor plan. In this example, floor plan input 701 also includes the total room area.

Furniture input 702 includes a number of furniture types and quantities. Other information used but not part of the input includes known furniture information 703 such as furniture dimensions, compatibility between rooms and furniture, and compatibility between furniture.

In this example, room layer graph generation 710 generates room layer graph 711 and room layout image 712 using floor plan input 701. In some illustrative examples, multiple room layout images are generated for selection. Further in this example, furniture layer graph generation 714 generates furniture layer graph 715 using furniture input 702 and known furniture information 703.

Room layer graph 711 and furniture layer graph 715 are used to generate multilayer graph 716. In this example, room layout image 712 is also part of output 718.

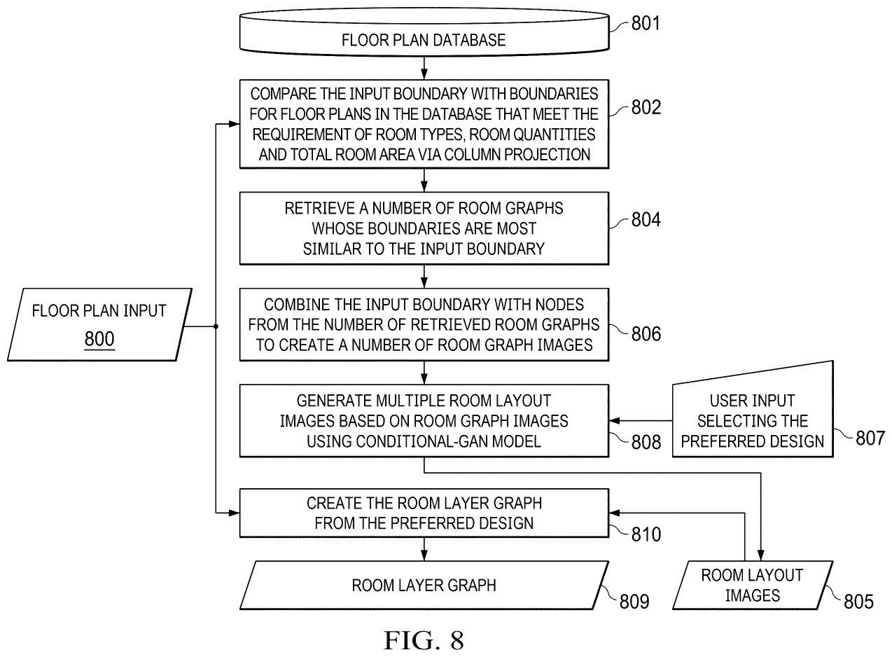

With reference next to FIG. 8, a flow diagram of a process for generating a room layer graph is depicted in accordance with an illustrative embodiment. The process in FIG. 8 can be implemented in hardware, software, or both. When implemented in software, the process can take the form of program instructions that are run by a processor set located in one or more hardware devices in one or more computer systems. For example, the process can be implemented in layout generator 214 in computer system 212 in FIG. 2. This process can be used to generate room layer graph 240 in FIG. 2.

In this example, inputs to this process include floor plan input 800 and floor plan database 801. Floor plan input 800 includes an input boundary with external walls and doors, a total room area, and a number of room types and quantities for the floor plan. Floor plan database 801 includes floor plans that comprise boundaries and room graphs. These room graphs include nodes indicating the room types and positions of rooms. Edges connecting the nodes in these room graphs indicate the position relationship such as showing whether two rooms are adjacent to each other.

As depicted, the process compares the input boundary with boundaries for floor plans in the database that meet the requirement of room types, room quantities and total room area via column projection (step 802). In step 802, the column projections are used to generate pixel functions for the input boundary. These pixel functions are compared to pixel functions for boundaries for the floor plans in database 801 to compare the input boundary with boundaries for floor plans i.

The process retrieves a number of room graphs whose boundaries are most similar to the input boundary (step 804). In this example, the number of boundaries having a closest fit in step 804 can include more room graphs based on boundaries that are most similar to the input boundary. The amount of similarity can be a threshold based on user preferences or input.

The process combines the input boundary with the nodes from the number of retrieved room graphs to create a number of room graph images (step 806). In other words, a room graph image can be created for each room graph in the number of room graphs by placing the nodes from the room graph image into the input boundary. In this example, a room graph image includes nodes placed within the input boundary in which the nodes can have graphical indicators that indicate room types.

The process generates multiple room layout images based on room graph images using a conditional-GAN model (step 808). In step 808, room layout images include the external walls and doors. The room layout images include inside walls that have graphical indicators such as color, shading, fill, line type, or line thickness that indicates the room type. Room layout images 805 generated in step 808 are displayed on a human machine interface.

The process creates a room layer graph from the preferred design (step 810). In this example, user input selecting the preferred design 807 is used to identify the room layout image that is used to generate room layer graph 809.

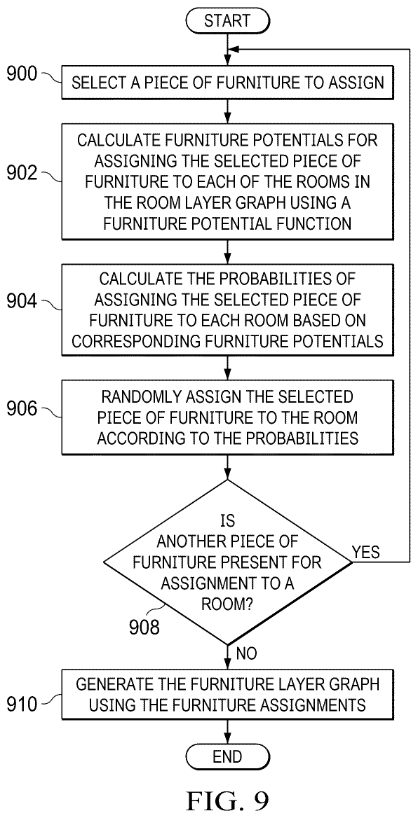

Turning now to FIG. 9, a flow diagram of a process for generating a furniture layer graph is depicted in accordance with an illustrative embodiment. The process in FIG. 9 can be implemented in hardware, software, or both. When implemented in software, the process can take the form of program instructions that are run by a processor set located in one or more hardware devices in one or more computer systems. For example, the process can be implemented in layout generator 214 in computer system 212 in FIG. 2. This process can be used to generate furniture layer graph 241 in FIG. 2.

In this example, the process assigns furniture to rooms in stages. Subsequent stages of furniture assignment takes into account furniture assigned in prior stages. This process can be performed for any number of stages in which each stage represents the assignment of the piece of furniture to a room. As a result, the number of stages depends on the number of pieces of furniture to be assigned.

The process begins by selecting a piece of furniture to assign (step 900). The process calculates furniture potentials for assigning the selected piece of furniture to each of the rooms in the room layer graph using a furniture potential function (step 902). In step 902, the furniture potentials are calculated at each stage for the piece of furniture selected to be assigned to all available rooms according to the compatibility between the furniture and the rooms, the remaining available area in each room, and the compatibility between the furniture and those already in the room.

The process calculates the probabilities of assigning the selected piece of furniture to each room based on corresponding furniture potentials (step 904). In this example, the probability measures the likelihood of an event occurring whose value range should be from 0 to 1. The larger the probability is, the more likely the event occurs. In this example, the probability implies the likelihood of assigning the selected piece of furniture to a room. In step 902, the furniture potentials may not be in the range of 0 to 1. In this example, a function such as a softmax can be used to convert the values, except for 0, into the range 0 to 1 in obtaining the probabilities.

The process randomly assigns the selected piece of furniture to the room according to the probabilities (step 906). A determination is made as to whether another piece of furniture is present for assignment to a room (step 908). If another piece of furniture is present for assignment, the process returns to step 900.

Otherwise, the process generates the furniture layer graph using the furniture assignments (step 910). The process terminates thereafter.

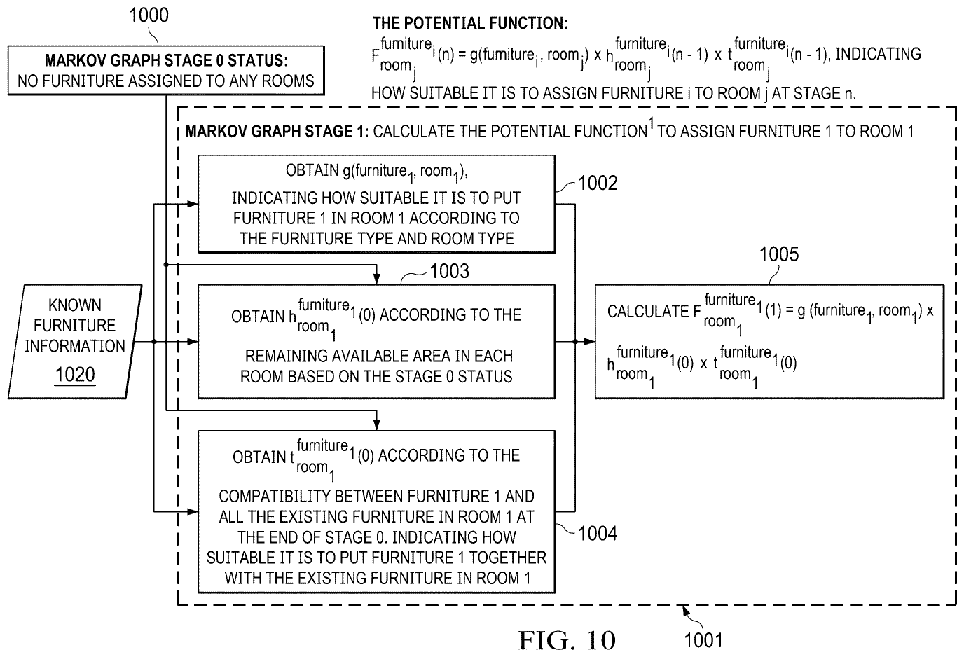

With reference next to FIG. 10, a flow diagram for determining the furniture potential value from a furniture potential function is depicted in accordance with an illustrative embodiment. The process in this flow diagram is an example of the calculation of a furniture potential that can be used in step 902 in FIG. 9.

In this example, known furniture information 1020 is an input into the process. In this example, known furniture information 1020 includes furniture sizes, compatibility between rooms and furniture, and compatibility of furniture with each other. In Markov graph stage 0 status 1000 no furniture is assigned to any of the rooms. All the rooms are currently empty at this stage.

Next in Markov graph stage 1 1001, the furniture potentials to assign furniture 1 to all rooms are calculated using the furniture potential function. In this example, the process obtains g(furniture₁, room₁), indicating how suitable it is to put furniture 1 in room 1 according to the furniture type and room type (step 1002). The process then obtains

$${h}_{{room}_{1}}^{{furniture}_{1}} ( 0 )$$

according to the remaining available area in each room based on the Stage 0 status (step 1003). In step 1003, if the remaining available area in room 1 is not larger than the size of furniture 1,

$${h}_{{room}_{1}}^{{furniture}_{1}} ( 0 ) = 0 .$$

### Otherwise,

$${h}_{{room}_{1}}^{{furniture}_{1}} ( 0 )$$

equals the ratio of the remaining available area in room 1 to the total remaining available area in all rooms at the end of Stage 0. The use of the ratio tends to avoid making rooms too empty or crowded.

The process obtains

$${t}_{{room}_{1}}^{{furniture}_{1}} ( 0 )$$

according to the compatibility between furniture 1 and all the existing furniture in room 1 at the end of Stage 0, indicating how suitable it is to put furniture 1 together with the existing furniture in room 1 (step 1004). The process then calculates

$${F}_{{room}_{1}}^{{furniture}_{1}} ( 1 ) = g ( {furniture}_{1} , {room}_{1} ) \times {h}_{{room}_{1}}^{{furniture}_{1}} ( 0 ) \times {t}_{{room}_{1}}^{{furniture}_{1}} ( 0 )$$

(step 1005). In step 1005, the furniture potential is determined for assigning furniture 1 to room 1 using the furniture potential function

$${F}_{{room}_{1}}^{{furniture}_{1}} ( 1 ) .$$

In Markov graph stage 1 1001, the process repeats these steps for furniture 1 for each room to complete determining furniture potentials for assigning furniture 1 to the different rooms. The process can be repeated for determining furniture potentials for assigning another piece of furniture to different rooms for each stage. These furniture potentials can then be used to determine the probabilities used to assign the furniture to the rooms.

The calculations to assign furniture 1 to room 1 in this figure are shown as an example of calculations used to assign furniture. Other calculations are present but not shown, such as the potential function to assign furniture 1 to room 2 and other rooms. Similar calculations are performed to assign other pieces of furniture to rooms in a similar manner to assigning furniture 1 to room 1.

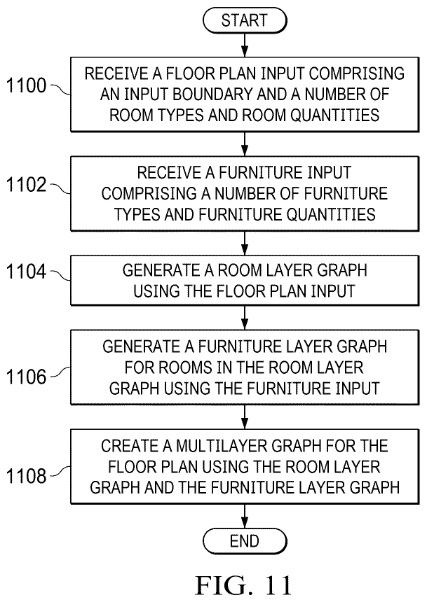

Turning next to FIG. 11, a flowchart of a process for creating a floor plan is depicted in accordance with an illustrative embodiment. The process in FIG. 11 can be implemented in hardware, software, or both. When implemented in software, the process can take the form of program instructions that are run by a processor set located in one or more hardware devices in one or more computer systems. For example, the process can be implemented in layout generator 214 in computer system 212 in FIG. 2.

The process receives a floor plan input comprising an input boundary and a number of room types and room quantities (step 1100). The process receives a furniture input comprising a number of furniture types and furniture quantities (step 1102). The process generates a room layer graph using the floor plan input (step 1104). The process generates a furniture layer graph for rooms in the room layer graph using the furniture input (step 1106).

The process creates a multilayer graph for the floor plan using the room layer graph and the furniture layer graph (step 1108). The process terminates thereafter.

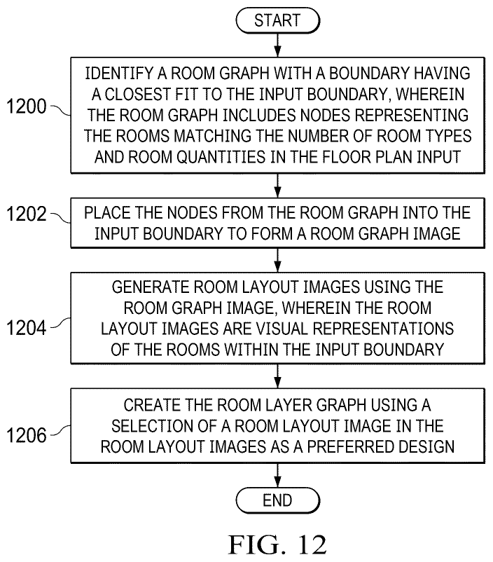

Turning to FIG. 12, a flowchart of a process for generating a room layer graph is depicted in accordance with an illustrative embodiment. The process in this flowchart is an example of steps that can be used to implement step 1104 in FIG. 11.

The process identifies a room graph with a boundary having a closest fit to the input boundary, wherein the room graph includes nodes representing the rooms matching the number of room types and room quantities in the floor plan input (step 1200). The process places the nodes from the room graph into the input boundary to form a room graph image (step 1202).

The process generates room layout images using the room graph image, wherein the room layout images are visual representations of the rooms within the input boundary (step 1204). The process creates the room layer graph using a selection of a room layout image in the room layout images as a preferred design (step 1206). The process terminates thereafter.

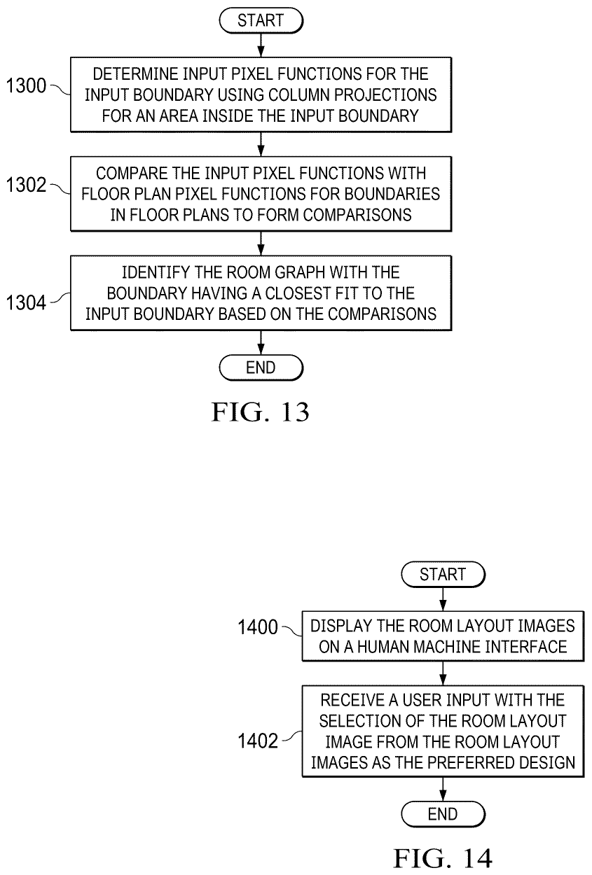

Turning to FIG. 13, a flowchart of a process for identifying a room graph is depicted in accordance with an illustrative embodiment. The process in this flowchart is an example of steps that can be used to implement step 1200 in FIG. 12.

The process determines input pixel functions for the input boundary using column projections for an area inside the input boundary (step 1300). The process compares the input pixel functions with floor plan pixel functions for boundaries in floor plans to form comparisons (step 1302).

The process identifies the room graph with the boundary having a closest fit to the input boundary based on the comparisons (step 1304). The process terminates thereafter.

Next in FIG. 14, a flowchart of a process for generating a room layer graph is depicted in accordance with an illustrative embodiment. The process in this flowchart is an example of additional steps that can be performed with the steps in FIG. 12.

The process displays the room layout images on a human machine interface (step 1400). The process receives a user input with the selection of the room layout image from the room layout images as the preferred design (step 1402). The process terminates thereafter.

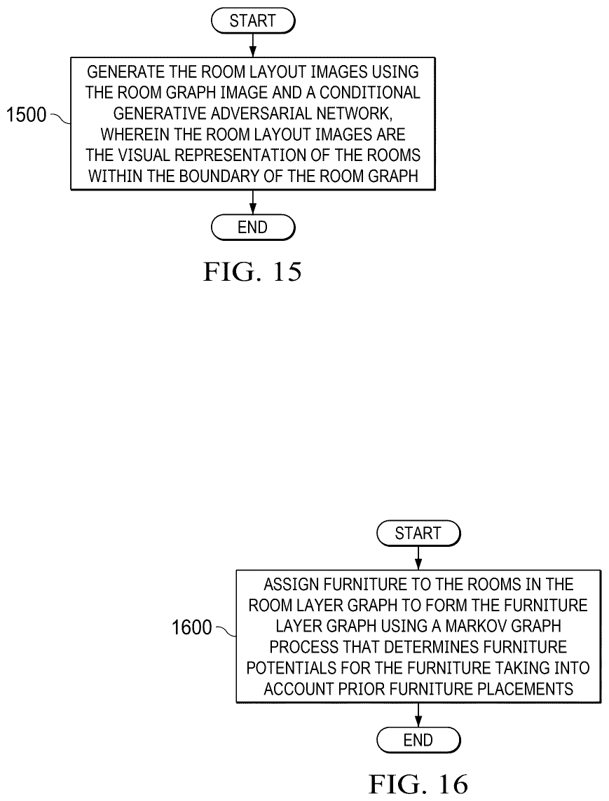

Turning to FIG. 15, a flowchart of a process for generating room layout images is depicted in accordance with an illustrative embodiment. The process in this figure is an example of an implementation of step 1204 in FIG. 12.

The process generates the room layout images using the room graph image and a conditional generative adversarial network, wherein the room layout images are the visual representation of the rooms within the boundary of the room graph (step 1500). The process terminates thereafter.

With reference now to FIG. 16, a flowchart of a process for generating furniture layer graphs is depicted in accordance with an illustrative embodiment. The process in this figure is an example of an implementation of step 1106 in FIG. 11.

The process assigns furniture to the rooms in the room layer graph to form the furniture layer graph using a Markov graph process that determines furniture potentials for the furniture taking into account prior furniture placements (step 1600). The process terminates thereafter. In step 1600, the furniture potentials take into account a suitability of the furniture based on a furniture type and a room type; a remaining available area in the rooms; and a compatibility between the furniture in a room.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks can be implemented as program instructions, hardware, or a combination of the program instructions and hardware. When implemented in hardware, the hardware may, for example, take the form of integrated circuits that are manufactured or configured to perform one or more operations in the flowcharts or block diagrams. When implemented as a combination of program instructions and hardware, the implementation may take the form of firmware. Each block in the flowcharts or the block diagrams can be implemented using special purpose hardware systems that perform the different operations or combinations of special purpose hardware and program instructions run by the special purpose hardware.

In some alternative implementations of an illustrative embodiment, the function or functions noted in the blocks may occur out of the order noted in the figures. For example, in some cases, two blocks shown in succession can be performed substantially concurrently, or the blocks may sometimes be performed in the reverse order, depending upon the functionality involved. Also, other blocks can be added in addition to the illustrated blocks in a flowchart or block diagram.

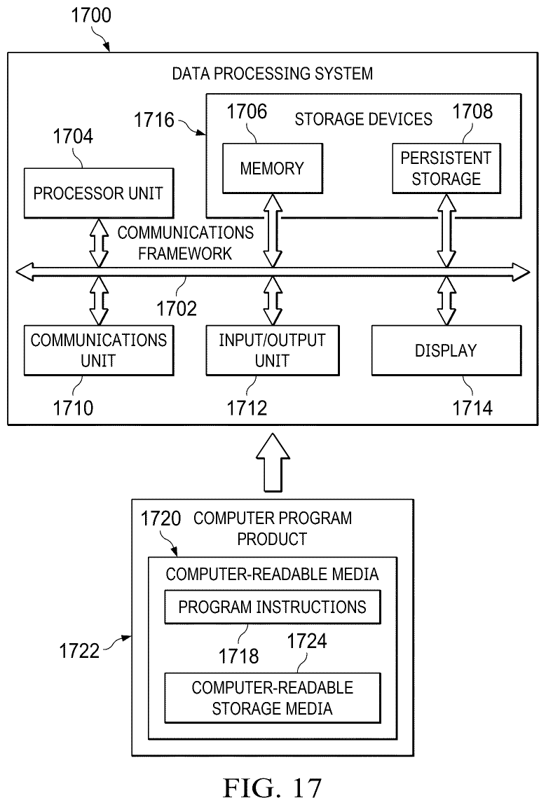

Turning now to FIG. 17, a block diagram of a data processing system is depicted in accordance with an illustrative embodiment. Data processing system 1700 can be used to implement computers and computing devices in computing environment 100 in FIG. 1. Data processing system 1700 can also be used to implement computer system 212 in FIG. 2. In this illustrative example, data processing system 1700 includes communications framework 1702, which provides communications between processor unit 1704, memory 1706, persistent storage 1708, communications unit 1710, input/output (I/O) unit 1712, and display 1714. In this example, communications framework 1702 takes the form of a bus system.

Processor unit 1704 serves to execute instructions for software that can be loaded into memory 1706. Processor unit 1704 includes one or more processors. For example, processor unit 1704 can be selected from at least one of a multicore processor, a central processing unit (CPU), a graphics processing unit (GPU), a physics processing unit (PPU), a digital signal processor (DSP), a network processor, or some other suitable type of processor. Further, processor unit 1704 can be implemented using one or more heterogeneous processor systems in which a main processor is present with secondary processors on a single chip. As another illustrative example, processor unit 1704 can be a symmetric multi-processor system containing multiple processors of the same type on a single chip.

Memory 1706 and persistent storage 1708 are examples of storage devices 1716. A storage device is any piece of hardware that is capable of storing information, such as, for example, without limitation, at least one of data, program instructions in functional form, or other suitable information either on a temporary basis, a permanent basis, or both on a temporary basis and a permanent basis. Storage devices 1716 may also be referred to as computer-readable storage devices in these illustrative examples. Memory 1706, in these examples, can be, for example, a random-access memory or any other suitable volatile or non-volatile storage device. Persistent storage 1708 may take various forms, depending on the particular implementation.

For example, persistent storage 1708 may contain one or more components or devices. For example, persistent storage 1708 can be a hard drive, a solid-state drive (SSD), a flash memory, a rewritable optical disk, a rewritable magnetic tape, or some combination of the above. The media used by persistent storage 1708 also can be removable. For example, a removable hard drive can be used for persistent storage 1708.

Communications unit 1710, in these illustrative examples, provides for communications with other data processing systems or devices. In these illustrative examples, communications unit 1710 is a network interface card.

Input/output unit 1712 allows for input and output of data with other devices that can be connected to data processing system 1700. For example, input/output unit 1712 may provide a connection for user input through at least one of a keyboard, a mouse, or some other suitable input device. Further, input/output unit 1712 may send output to a printer. Display 1714 provides a mechanism to display information to a user.

Instructions for at least one of the operating system, applications, or programs can be located in storage devices 1716, which are in communication with processor unit 1704 through communications framework 1702. The processes of the different embodiments can be performed by processor unit 1704 using computer-implemented instructions, which may be located in a memory, such as memory 1706.

These instructions are referred to as program instructions, computer usable program instructions, or computer-readable program instructions that can be read and executed by a processor in processor unit 1704. The program instructions in the different embodiments can be embodied on different physical or computer-readable storage media, such as memory 1706 or persistent storage 1708.

Program instructions 1718 are located in a functional form on computer-readable media 1720 that is selectively removable and can be loaded onto or transferred to data processing system 1700 for execution by processor unit 1704. Program instructions 1718 and computer-readable media 1720 form computer program product 1722 in these illustrative examples. In the illustrative example, computer-readable media 1720 is computer-readable storage media 1724.

Computer-readable storage media 1724 is a physical or tangible storage device used to store program instructions 1718 rather than a medium that propagates or transmits program instructions 1718. Computer-readable storage media 1724, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Alternatively, program instructions 1718 can be transferred to data processing system 1700 using a computer-readable signal media. The computer-readable signal media are signals and can be, for example, a propagated data signal containing program instructions 1718. For example, the computer-readable signal media can be at least one of an electromagnetic signal, an optical signal, or any other suitable type of signal. These signals can be transmitted over connections, such as wireless connections, optical fiber cable, coaxial cable, a wire, or any other suitable type of connection.

Further, as used herein, “computer-readable media 1720” can be singular or plural. For example, program instructions 1718 can be located in computer-readable media 1720 in the form of a single storage device or system. In another example, program instructions 1718 can be located in computer-readable media 1720 that is distributed in multiple data processing systems. In other words, some instructions in program instructions 1718 can be located in one data processing system while other instructions in program instructions 1718 can be located in one data processing system. For example, a portion of program instructions 1718 can be located in computer-readable media 1720 in a server computer while another portion of program instructions 1718 can be located in computer-readable media 1720 located in a set of client computers.

The different components illustrated for data processing system 1700 are not meant to provide architectural limitations to the manner in which different embodiments can be implemented. In some illustrative examples, one or more of the components may be incorporated in or otherwise form a portion of, another component. For example, memory 1706, or portions thereof, may be incorporated in processor unit 1704 in some illustrative examples. In other examples, more than one processor unit can be present. The different illustrative embodiments can be implemented in a data processing system including components in addition to or in place of those illustrated for data processing system 1700. Other components shown in FIG. 17 can be varied from the illustrative examples shown. The different embodiments can be implemented using any hardware device or system capable of running program instructions 1718.

Thus, illustrative embodiments of the present invention provide a computer implemented method, computer system, and computer program product for creating floor plans. In one example, a method creates a floor plan. A floor plan input comprising an input boundary and a number of room types and room quantities is received. A furniture input comprising a number of furniture types and furniture quantities is received. A room layer graph is generated using the floor plan input. A furniture layer graph for rooms in the room layer graph is generated using the furniture input. A multilayer graph for the floor plan is created using the room layer graph and the furniture layer graph.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

The descriptions of the various embodiments of the present invention have been presented for purposes of illustration, but are not intended to be exhaustive or limited to the embodiments disclosed. Not all embodiments will include all of the features described in the illustrative examples. Further, different illustrative embodiments may provide different features as compared to other illustrative embodiments. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A method for creating a floor plan, the method comprising:
receiving a floor plan input comprising an input boundary and a number of room types and room quantities;
receiving a furniture input comprising a number of furniture types and furniture quantities;
generating a room layer graph using the floor plan input;
generating a furniture layer graph for rooms in the room layer graph using the furniture input; and
creating a multilayer graph for the floor plan using the room layer graph and the furniture layer graph.

2. The method of claim 1, wherein generating the room layer graph comprises:
identifying a room graph with a boundary having a closest fit to the input boundary, wherein the room graph includes nodes representing the rooms matching the number of room types and the room quantities in the floor plan input;
placing the nodes from the room graph into the input boundary to form a room graph image;
generating room layout images using the room graph image, wherein the room layout images are visual representations of the rooms within the input boundary; and
creating the room layer graph using a selection of a room layout image in the room layout images as a preferred design.

3. The method of claim 2, wherein identifying the room graph comprises:
determining input pixel functions for the input boundary using column projections for an area inside the input boundary;
comparing the input pixel functions with floor plan pixel functions for boundaries in floor plans to form comparisons; and
identifying the room graph with the boundary having a closest fit to the input boundary based on the comparisons.

4. The method of claim 2, wherein generating the room layer graph further comprises:
displaying the room layout images on a human machine interface; and
receiving a user input with the selection of the room layout image from the room layout images as the preferred design.

5. The method of claim 2, wherein generating the room layout images comprises:
generating the room layout images using the room graph image and a conditional generative adversarial network, wherein the room layout images are the visual representation of the rooms within the boundary of the room graph.

6. The method of claim 1, wherein generating the furniture layer graph comprises:
assigning furniture to the rooms in the room layer graph to form the furniture layer graph using a Markov graph process that determines furniture potentials for the furniture taking into account prior furniture placements.

7. The method of claim 6, wherein the furniture potentials take into account a suitability of the furniture based on a furniture type and a room type; a remaining available area in the rooms; and a compatibility between the furniture in a room.

8. The method of claim 1, wherein the floor plan input further comprises a total room area and wherein areas of rooms in the room layer graph are based on a total room area, a boundary area inside the input boundary and a room area of each room in the room layout image.

9. A computer system comprising:
a processor set;
a set of one or more computer-readable storage media; and
program instructions, collectively stored in the set of one or more storage media to cause the processor set to perform operations comprising:
receiving a floor plan input comprising an input boundary and a number of room types and room quantities;
receiving a furniture input comprising a number of furniture types and furniture quantities;
generating a room layer graph using the floor plan input;
generating a furniture layer graph for rooms in the room layer graph using the furniture input; and
creating a multilayer graph for a floor plan using the room layer graph and the furniture layer graph.

10. The computer system of claim 9, wherein generating the room layer graph comprises:
identifying a room graph with a boundary having a closest fit to the input boundary, wherein the room graph includes nodes representing the rooms matching the number of room types and the room quantities in the floor plan input;
placing the nodes from the room graph into the input boundary to form a room graph image;
generating room layout images using the room graph image, wherein the room layout images are visual representations of the rooms within the boundary; and
creating the room layer graph using a selection of a room layout image in the room layout images as a preferred design.

11. The computer system of claim 10, wherein identifying the room graph comprises:
determining an input pixel function for the input boundary using column projections for an area inside the input boundary;
comparing the input pixel function with floor plan pixel functions for boundaries in floor plans to form comparisons; and
identifying the room graph with the boundary having a closest fit to the input boundary based on the comparisons.

12. The computer system of claim 10, wherein generating the room layer graph further comprises:
displaying the room layout images on a human machine interface; and
receiving a user input with the selection of the room layout image from the room layout images as the preferred design.

13. The computer system of claim 10, wherein generating the room layout images comprises:
generating the room layout images using the room graph image and a conditional generative adversarial network, wherein the room layout images are the visual representation of the rooms within the boundary of the room graph.

14. The computer system of claim 9, wherein generating the furniture layer graph comprises:
assigning furniture to the rooms in the room layer graph to form the furniture layer graph using a Markov graph process that determines furniture potentials for the furniture taking into account prior furniture placements.

15. The computer system of claim 14, wherein the furniture potentials take into account a suitability of the furniture based on a furniture type and a room type; a remaining available area in the rooms; and a compatibility between the furniture in a room.

16. The computer system of claim 9, wherein the floor plan input further comprises a total room area and wherein areas of rooms in the room layer graph are based on a total room area, a boundary area inside the input boundary and a room area of each room in the room layout image.

17. A computer program product for creating a floor plan, the computer program product comprising:
a set of one or more computer-readable storage media;
program instructions stored on the set of one or more storage media to perform operations comprising:
receiving a floor plan input comprising an input boundary and a number of room types and room quantities;
receiving a furniture input comprising a number of furniture types and furniture quantities;
generating a room layer graph using the floor plan input;
generating a furniture layer graph for rooms in the room layer graph using the furniture input; and
creating a multilayer graph for the floor plan using the room layer graph and the furniture layer graph.

18. The computer program product of claim 17, wherein generating the room layer graph comprises:
identifying a room graph with a boundary having a closest fit to the input boundary, wherein the room graph includes nodes representing the rooms matching the number of room types and the room quantities in the floor plan input;
placing the nodes from the room graph into the input boundary to form a room graph image;
generating room layout images using the room graph image, wherein the room layout images are visual representations of the rooms within the boundary; and
creating the room layer graph using a selection of a room layout image in the room layout images as a preferred design.

19. The computer program product of claim 18, wherein identifying the room graph comprises:
determining input pixel functions for the input boundary using column projections for an area inside the input boundary;
comparing the input pixel functions with floor plan pixel functions for boundaries in floor plans to form comparisons; and
identifying the room graph with the boundary having a closest fit to the input boundary based on the comparisons.

20. The computer program product of claim 18, wherein generating the room layer graph further comprises:
displaying the room layout images on a human machine interface; and
receiving a user input with the selection of the room layout image from the room layout images as the preferred design.
